(19) United States
(12) Patent Application Publication
(10) Pub. No.: US 2026/0269343 A1
(43) Pub. Date: Sep. 10, 2026

(54) ASSEMBLY WITH BATTERY STATUS DISPLAY

(71) Applicant: Also, Inc., Palo Alto, CA (US)

(72) Inventors: Patrick HARRINGTON, Asheville, NC (US); Sanket Parshuram PHALGAONKAR, San Francisco, CA (US); Adam Christopher BENDER, San Francisco, CA (US); Yale CHEN, San Jose, CA (US)

(73) Assignee: Also, Inc., Palo Alto, CA (US)

(21) Appl. No.: 19/558,083

(22) Filed: Mar. 5, 2026

Related U.S. Application Data
(60) Provisional application No. 63/767,721, filed on Mar. 6, 2025.

(51) Int. Cl. H01M 10/48; B60L 50/64; B62M 6/90; H01M 50/244; H01M 50/249; H05K 7/20; G02F 1/15

(52) U.S. Cl. CPC H01M 10/482; B60L 50/64; B62M 6/90; H01M 10/488; H01M 50/244; H01M 50/249; H05K 7/20963; B60L 2250/16; G02F 1/15; H01M 2220/20

(57) ABSTRACT

An assembly of a micromobility device can include a housing. The housing can include an exterior surface defining at least one aperture. The assembly can include one or more battery cells. The one or more battery cells can power the micromobility device. The assembly can include a display assembly. The assembly can include a battery pack assembly. The housing can receive the battery pack assembly and the display assembly. The display assembly can be disposed interior to the exterior surface of the housing such that a display device aligns with the at least one aperture. The display device can present a status of the one or more battery cells based on a power level of the one or more battery cells. The display device can maintain presentation of the status of the one or more battery cells while requiring substantially no power to maintain the presentation of the status.

### CROSS-REFERENCE TO RELATED PATENT APPLICATIONS

This application claims the benefit of and priority to U.S. Provisional Patent Application No. 63/767,721, filed Mar. 6, 2025, the entirety of which is incorporated by reference herein for all purposes.

### BACKGROUND

Micromobility devices, such as bicycles, can include energy storage devices.

### SUMMARY

This disclosure is generally related to one or more components of a micromobility device. The micromobility device can include a bicycle, for example. The components of the micromobility device can include at least one assembly. The assembly can include one or more additional assemblies or sub-assemblies. For example, the assembly can include a battery pack assembly and a display assembly. The battery pack assembly can include one or more energy storage devices (e.g., batteries, cells, etc.) to power the bicycle. The display assembly can include a display device to present, provide, or otherwise display a status of the energy storage devices. For example, the display assembly can include an electronic ink (e.g., e-ink) display or display device to present a state of charge of one or more battery cells. As another example, the display device can present a visual or graphic depiction of when the battery cells are being provided with power or energy (e.g., when the battery cells are being charged).

At least one aspect is directed to an assembly of a micromobility device. The assembly can include a housing. The housing can include an exterior surface defining at least one aperture. The assembly can include one or more battery cells. The one or more battery cells can power the micromobility device. The assembly can include a display assembly. The assembly can include a battery pack assembly. The housing can receive the battery pack assembly and the display assembly. The display assembly can be disposed interior to the exterior surface of the housing such that a display device aligns with the at least one aperture. The display device can present a status of the one or more battery cells based on a power level of the one or more battery cells. The display device can maintain presentation of the status of the one or more battery cells while requiring substantially no power to maintain the presentation of the status.

At least one aspect is directed to an electric bicycle. The electric bicycle can include an assembly. The assembly can include a housing. The housing can include an exterior surface defining at least one aperture. The assembly can include one or more battery cells. The one or more battery cells can power the electric bicycle. The assembly can include a display assembly. The assembly can include a battery pack assembly. The housing can receive the battery pack assembly and the display assembly. The display assembly can be disposed interior to the exterior surface of the housing such that a display device aligns with the at least one aperture. The display device can present a status of the one or more battery cells based on a power level of the one or more battery cells. The display device can maintain presentation of the status of the one or more battery cells while requiring substantially no power to maintain the presentation of the status.

At least one aspect is directed to a method. The method can include providing a housing of an assembly of an electric bicycle. The housing can include an exterior surface defining at least one aperture. The housing can receive a battery pack assembly and a display assembly. The method can include disposing the battery pack assembly and the display assembly within the housing. The battery pack assembly can include one or more battery cells. The one or more battery cells can power the electric bicycle. The display assembly can be disposed interior to the exterior surface of the housing such that a display device aligns with the at least one aperture of the exterior surface. The display device can present a status of the one or more battery cells while requiring substantially no power to maintain presentation of the status.

At least one aspect is directed to an assembly. The assembly can be for an electric bicycle. The assembly can include a housing. The housing can receive a battery pack assembly of the assembly and a display assembly of the assembly. The battery pack assembly can store one or more battery cells. The one or more battery cells can power the electric bicycle. The display assembly can include a display device. The display device can continuously present a status of the one or more battery cells.

At least one aspect is directed to a method. The method can include providing a housing of an assembly. The assembly can be for an electric bicycle. The housing can receive a battery pack assembly of the assembly and a display assembly of the assembly. The method can include disposing the battery pack assembly and the display assembly within the housing. The battery pack assembly can store one or more battery cells. The one or more battery cells can power the electric bicycle. The display assembly can include a display device. The display device can continuously present a status of the one or more battery cells.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts an example bicycle, in accordance with some aspects.

FIG. 2A depicts an assembly, in accordance with some aspects.

FIG. 2B depicts the assembly of FIG. 2A, in accordance with some aspects.

FIG. 2C depicts the assembly of FIG. 2A, in accordance with some aspects.

FIG. 3 depicts the assembly of FIG. 2A, in accordance with some aspects.

FIG. 4A is a perspective view of the assembly of FIG. 2A, in accordance with some aspects.

FIG. 4B is a perspective view of the assembly of FIG. 2A, in accordance with some aspects.

FIG. 5A is a perspective view of the assembly of FIG. 2A, in accordance with some aspects.

FIG. 5B is a perspective view of the assembly of FIG. 2A, in accordance with some aspects.

FIG. 5C is a perspective view of the assembly of FIG. 2A, in accordance with some aspects.

FIG. 6A depicts a display assembly of the assembly of FIG. 2A, in accordance with some aspects.

FIG. 6B depicts a display assembly of the assembly of FIG. 2A, in accordance with some aspects.

FIG. 7 is a perspective view of a sub-assembly that includes the display assembly of FIG. 6A disposed within a sub-housing, in accordance with some aspects.

FIG. 8A is a perspective view of the sub-assembly of FIG. 7, in accordance with some aspects.

FIG. 8B is a perspective view of the sub-assembly of FIG. 7, in accordance with some aspects.

FIG. 8C is a perspective view of the sub-assembly of FIG. 7, in accordance with some aspects.

FIG. 9 is a perspective view of the display assembly of FIG. 6A disposed within a housing of the assembly of FIG. 2A, in accordance with some aspects.

FIG. 10 is a perspective view of the display assembly of FIG. 6A disposed within the housing of the assembly of FIG. 2A, in accordance with some aspects.

FIG. 11 depicts a status of one or more battery cells, in accordance with some aspects.

FIG. 12 depicts a status of one or more battery cells, in accordance with some aspects.

FIG. 13 depicts a status of one or more battery cells, in accordance with some aspects.

FIG. 14 depicts a status of one or more battery cells, in accordance with some aspects.

FIG. 15 depicts a status of one or more battery cells, in accordance with some aspects.

FIG. 16 depicts a status of one or more battery cells, in accordance with some aspects.

FIG. 17 depicts a status of one or more battery cells, in accordance with some aspects.

FIG. 18 depicts a perspective view of a display device including one or more pixels, in accordance with some aspects.

FIG. 19 is a block diagram illustrating an architecture for a computer system that can be employed to implement elements of the systems and methods described and illustrated herein.

FIG. 20 is a flow diagram of a process to provide an assembly, in accordance with some aspects.

### DETAILED DESCRIPTION

Following below are more detailed descriptions of various concepts related to, and implementations of, methods, apparatuses, and systems of one or more assemblies for a micromobility device, such as a bicycle. The various concepts introduced above and discussed in greater detail below may be implemented in any way of numerous ways.

The present disclosure is directed to one or more components for a micromobility device. The micromobility device can be or include a bicycle, for example. The components of the micromobility device can include one or more assemblies, such as a battery pack assembly and a display assembly. The display assembly can present information associated with a status of one or more aspects of the battery pack assembly. For example, the display assembly can display a state of charge of one or more battery cells of the battery pack assembly.

Assemblies that house or otherwise include battery cells can include icons, display elements, or other visual cues to present information associated with the battery cells. For example, standalone battery packs can include buttons or other input devices that, when interacted with (e.g., touched, pressed, toggled, etc.), cause light sources to illuminate. However, these standalone battery packs may not present a continuous status (e.g., always on, continuously on, etc.) regarding the batteries. As a result, in order to be presented with the status of the batteries, an operator of this standalone battery pack is required to interact or interface with the battery pack to receive a status of batteries. Moreover, the operator may need to be within arm’s reach of this standalone battery pack to be able to interact with the battery pack such that the status of the batteries is displayed. Furthermore, if standalone battery packs were to provide a continuous status of the batteries, the energy stored by the battery packs would be depleted over time due to the high power draw associated with powering the light sources of these standalone battery packs.

The disclosed solutions have a technical advantage of providing an assembly that includes display assembly having a display device to provide a continuous status of one or more batteries with minimal power draw. For example, the display device can include an electronic ink display which can provide an always on experience with respect to the state of charge of one or more batteries of a battery pack assembly that is disposed within a main housing of the assembly. The electronic ink display can present information (e.g., state of charge, charging, etc.) regarding the batteries without having to first receive an input (e.g., a touch, a press, a toggle, etc.) that indicates a request for presentation of the information. Advantageously, an operator of the assembly can quickly be presented the status of information by simply looking towards the assembly as the display device (of the display assembly) can be continuously active, on, or in a constant state of display.

The present technical solution also includes arranging or placing the display assembly within its own sub-housing such that the display assembly can be removable from the overall assembly or main housing without having to remove any additional components within the main housing. For example, the display assembly can be located within a sub-housing (of the overall assembly of the main housing). The sub-housing can attach to or couple with the main housing of the overall assembly. The sub-housing can couple with the housing via one or more fasteners (e.g., bolts, screws, pins, etc.) which, upon removal of the fasteners can free the sub-housing.

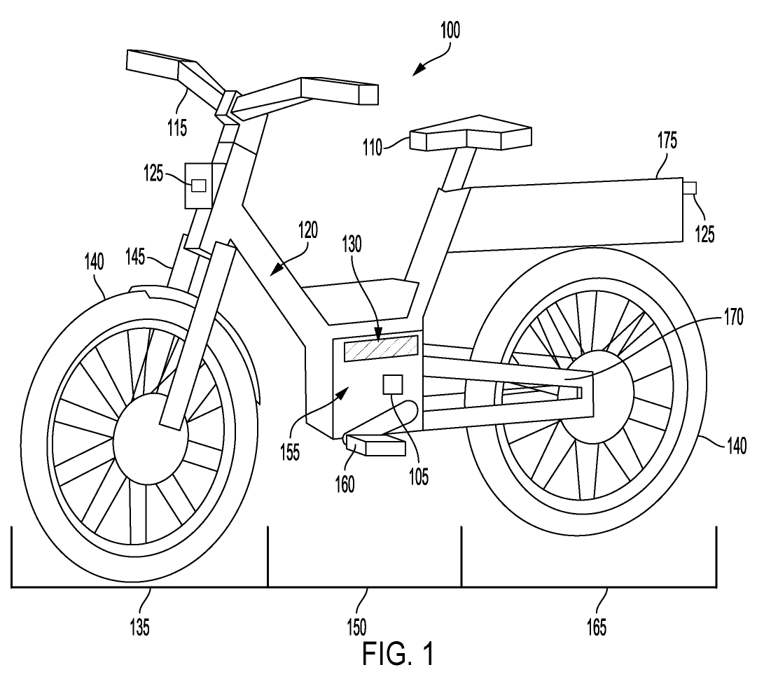

FIG. 1 depicts an example perspective view of a micromobility device, such as a bicycle (referred to generally herein as bike 100, which is understood to include a reference to any micromobility device). The bike 100 can be an electric bike installed with at least one battery pack (shown as battery pack 105). The bike 100 can include at least one bicycle. The bike 100 can be a human-operated bike. The bike 100 can include single rider bicycles, tandem bicycles, cargo bicycles, motor-assist bicycles, pedicabs, electric-assist bicycles, road bicycles, mountain bicycles, or unicycles, among others. The battery pack 105 can also be used as an energy storage system to power a building, such as a residential home or commercial building. The bike 100 can be fully electric or partially electric (e.g., pedal-powered) and further, the bike 100 can be fully autonomous, partially autonomous, semi-autonomous, or unmanned. The bike 100 can also be human operated or non-autonomous. A human operator or the rider of the bike 100 can sit on a saddle 110 to operate the bike 100. The rider of the bike 100 can steer, grip, balance, or otherwise control the bike 100 using the handlebar 115.

The battery pack 105 can refer to or include at least one of an assembly, a sub-assembly, a standalone device, or other possible components or apparatuses. While the battery pack 105, in some examples, has been described as a separate or discrete element of the bike 100, the battery pack 105 can be included in an assembly which further includes one or more additional sub-assemblies. The battery pack 105 can be housed or otherwise located within a housing that further houses additional elements/assemblies of the bike 100.

The bike 100 can include a frame 120. The frame 120 can support various components of the bike 100, such as a handlebar 115, the saddle 110, the battery pack 105, at least one light (shown as light 125), and at least one lock assembly (shown as lock assembly 130). The frame 120 can span a front portion 135. The front portion 135 can support, be coupled with, or include, for example, a wheel 140 of the bike 100, a fork 145 of the bike 100, the handlebar 115, the light 125, among other components. The bike 100 can include two or more wheels 140 (e.g., a front wheel 140 and a rear wheel 140). The frame 120 can span a middle portion 150. The middle portion 150 can support, be coupled with, or include, for example, the saddle 110, the battery pack 105, a crank shaft or drive mechanism (shown as drive mechanism 155) of the bike 100, or a pedal 160 of the bike 100, among other components. The frame 120 can include the middle portion 150 including the lock assembly 130. The frame 120 can include a rear portion 165. The rear portion 165 can support, be coupled with, or include, for example, a rear wheel 140 of the bike 100, the light 125, a drive train 170 of the bike 100, or a rack 175 of the bike 100, among other components. The battery pack 105 can be disposed anywhere within the frame 120.

The battery pack 105 can include at least one battery, at least one battery module, or at least one battery cell. The battery pack 105 can be electrically coupled with the bike 100 (e.g., to the drive mechanism 155, to the light 125, the lock assembly 130, or some other components). For example, the battery pack 105 can provide electrical energy to the bike 100 to power the bike 100. The battery pack 105 can be installed or placed within the bike 100. For example, the battery pack 105 can be installed on the frame 120 of the bike 100 within one or more of the front portion 135, the middle portion 150, or the rear portion 165. The battery pack 105 can be integrally coupled with the frame 120 such that it is not removable. The battery pack 105 can be detachably coupled with the frame 120 such that the battery pack 105 can be removed (e.g., to charge the battery pack 105). The battery pack 105 can include or connect with at least one busbar, e.g., a current collector element. For example, the busbar can include electrically conductive material to connect or otherwise electrically couple the battery pack 105 with other electrical components of the bike 100 to provide electrical power to various systems or components of the bike 100, such as the lock assembly 130 or some other system.

As shown in FIG. 1, among others, the lock assembly 130 can be coupled with the frame 120. For example, the lock assembly 130 can be at least partially integrated with the frame 120 of the bike 100 such that at least a portion of the lock assembly 130 can be inseparable from, built within, permanently coupled with, or otherwise integrated with the frame 120 of the bike 100. The battery pack 105 can be coupled with the frame 120 via one or more receivers. The lock assembly 130 can be positioned within the middle portion 150 of the bike 100 and beneath the saddle 110 or proximate the drive mechanism 155 and pedal 160.

The bike 100 can include the lock assembly 130 electrically coupled with the battery pack 105. For example, the battery pack 105 can be electrically coupled with a receiver of the lock assembly 130 to facilitate the actuation or movement of one or more components of the receiver. In this way, the receiver can be configured to be controlled or actuated electronically via power provided by the battery pack 105, rather than being controlled or actuated manually or mechanically (e.g., via some manual action of an operator). For example, the battery pack 105 can provide power to the drive mechanism 155 to power the bike 100 (e.g., propel the bike by causing the at least one wheel 140 to rotate) and also provide power to the receiver to operate the lock assembly 130. The battery pack 105 can provide power to the lock assembly 130 and other components of the bike 100 (e.g., the drive mechanism 155, the light 125, or some other component) simultaneously, separately, in sequence, or in some other manner.

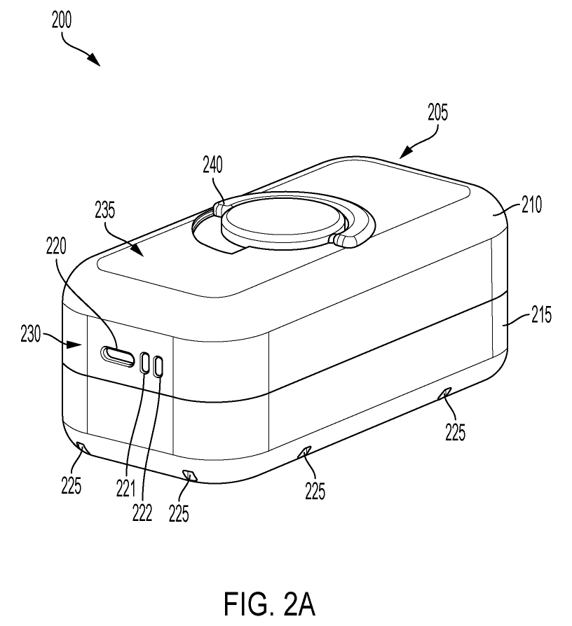

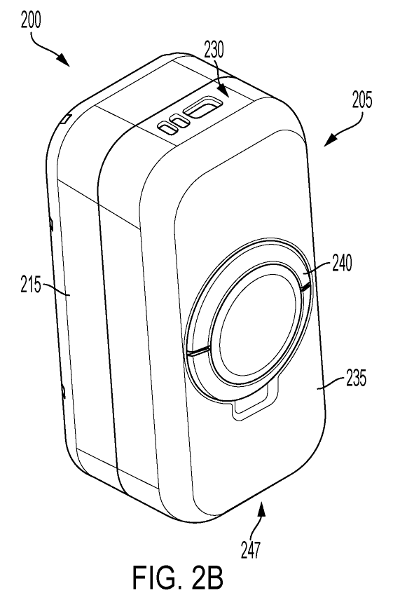

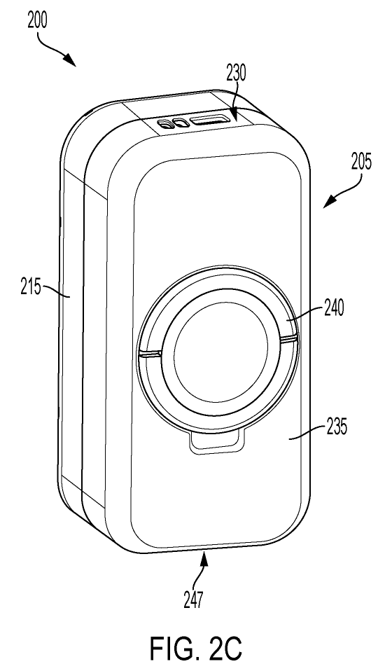

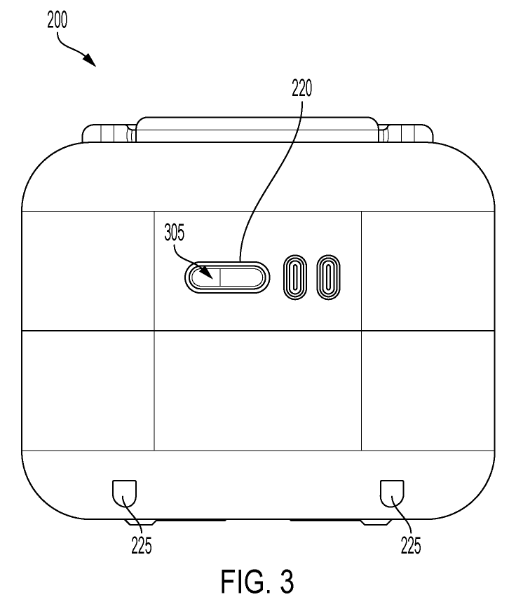

FIGS. 2A, 2B, 2C, and 3 depict perspective views of an assembly 200, in accordance with some aspects. For example, FIG. 2A depicts the assembly 200 in a horizontal placement or position such that the assembly 200 spans a horizontal axis. In contrast, FIGS. 2B and 2C depict (for example) the assembly 200 in a vertical placement or position such that the assembly 200 spans a vertical axis. The assembly 200 can include at least one of the assemblies described herein. For example, the assembly 200 can be an assembly of the bike 100. As another example, the assembly 200 can house or otherwise include the battery pack 105. The assembly 200 can include at least one housing (shown as housing 205). The housing 205 can define or dictate at least one of a size, a shape, a layout, of an arrangement of the assembly 200. For example, the housing 205 can define a dimension of the assembly 200. As another example, and as shown in FIG. 2A (among other figures), the housing 205 can define an oval shape for the assembly 200.

The housing 205 can include at least one portion or segment. For example, as shown in FIG. 2A, the housing 205 includes a top portion 210 and a bottom portion 215. The portions (e.g., the top portion 210 and the bottom portion 215) of the housing 205 can be removably coupled with one another. For example, the top portion 210 can be coupled with the bottom portion 215 via one or more fasteners. The top portion 210 or the bottom portion 215 can be removable responsive to the removal of the fasteners. The respective portions (e.g., the top portion 210 and the bottom portion 215) of the housing 205 can be opposite to one another. For example, the top portion 210 can represent a first side of the assembly 200 and the bottom portion 215 can represent a second side of the assembly 200 that is opposite to the first side.

The housing 205 can include at least one aperture or opening. For example, as shown in FIG. 2A, the top portion 210 includes an aperture 220, an aperture 221, and an aperture 222. The apertures can provide or otherwise create an opening for one or more components of the assembly 200. For example, the aperture 221 and the aperture 222 can provide respective openings such that a cable or cord can be plugged into or electrically coupled with the assembly 200. For example, the aperture 221 can provide an opening for a Universal Serial Bus (USB) cord to couple with the assembly 200. As another example, the aperture 222 can provide a port for an AC jack to couple with the assembly 200. Stated otherwise, the aperture 221 or the aperture 222 can define or otherwise provide an opening for an electrical receptacle or port (e.g., USB port) to receive an electrical connector or plug. As shown in FIG. 2A, for example, the apertures 220, 221, 222 (of the housing 205) can be collocated with one another such that the apertures can be side by side or otherwise next to one another. For example, an edge that partially defines at least one of apertures 220, 221, or 222 can be located less than one inch from an edge that partially defines another one of the apertures 220, 221, 222. The electrical receptacle (that is included with or accessible via the aperture 221 or the aperture 222) can provide current to one or more devices. For example, the electrical receptacle can provide bidirectional current flow such that current flows from the one or more battery cells or flows to the one or more battery cells. The bidirectional current flow can be to charge the one or more battery cells. The bidirectional current flow can be to power an external device, such as a mobile device, a tablet, a rechargeable flashlight, among other possible devices.

The assembly 200 can include at least one electrical contact, connector, or terminal. For example, as shown in FIG. 2A, the assembly includes contacts 225. The contacts 225 can be disposed on or otherwise located on at least one portion of the housing 205. For example, as shown in FIG. 2A, the contacts 225 are disposed on the bottom portion 215. Stated otherwise, the contacts 225 (as shown in FIG. 2A) are disposed opposite to the top portion 210. The contacts 225 can electrically couple the assembly 200 with the bike 100, one or more portions of the bike 100, or one or more components of the bike 100. For example, the contacts 225 can electrically couple the assembly 200 with the frame 120. As another example, the contacts can electrically couple one or more battery cells (of the assembly 200) with a drive unit or the drive train 170 of the bike 100. The contacts 225 can (when decoupled or removed from the bike 100) can electrically couple with a power source (e.g., a charging device, an outlet, etc.) to receive power to charge the battery cells of the assembly 200.

The assembly 200 can include at least one side or face. For example, as shown in FIG. 2A, the assembly 200 includes a front face 230 and a top face 235. The assembly 200 can also include a bottom face (that is located opposite to the top face 235) and a back face 247 (that is located opposite to the front face 230). The respective faces or sides (e.g., front face 230, top face 235, back face 247, bottom face, etc.) of the assembly 200 can refer to or include one or more of respective exterior boundaries or surfaces of the housing 205, respective exterior-facing regions of the housing 205, respective portions, sections, or segments of the housing 205, among other possibilities. As shown in FIG. 2A, the aperture 220, the aperture 221, and the aperture 222 can be disposed or otherwise position at or proximate to the front face 230.

The assembly 200 can include at least one member or element (shown as handle 240 in FIGS. 2A-2C) with which an operator can interface. For example, the operator of the bike 100 can grab (e.g., interface with) the handle 240 to remove or decouple the assembly 200 from the bike 100. The handle 240 can be movably coupled with the contacts 225 such that grabbing the handle 240 results in a movement (e.g., depression, compression, retraction, etc.) of the contacts 225. The movement of the contacts 225 can decouple the assembly 200 from the bike 100. Stated otherwise, the movement of the contacts 225 can result in the contacts 225 retracting into the housing 205 such that assembly 200 is no longer coupled with the bike 100. The handle 240 can include one or more members, such as two half-circles, that can move towards one another to release the contacts 225. For example, an operator can grab each half-circle (of the handle 240) which activates one or more springs or biasing element to cause the contacts to retract into the housing 205.

As shown in FIG. 2B and 2C, the top face 235 can span from or between the front face 230 and the back face 247 to define a length or other dimension of the assembly 200. For example, the top face 235 (spanning from the front face 230 to the back face 247) can establish an overall length of the housing 205. As another example, the length between the front face 230 and the back face 247 (e.g., the length of the top face 235) can establish a dimension of an internal cavity of the assembly 200.

As shown in FIG. 3, the aperture 220 can provide an opening such that a status 305 of one or more battery cells of the assembly 200 is visible. The aperture 220 can provide an opening for a display device (of the assembly 200) to present, provide, generate, or otherwise graphically or digitally display the status 305. For example, the assembly 200 can include an electronic ink display to present the status 305. The status 305 can correspond to or represent a status of the battery cells of the assembly 200. For example, the status 305 can represent or indicate a state of charge of the battery cells. As another example, the status 305 can represent or include an indication (e.g., an icon, an element, etc.) that the battery cells are being charged (e.g., receiving power, receiving energy, etc.).

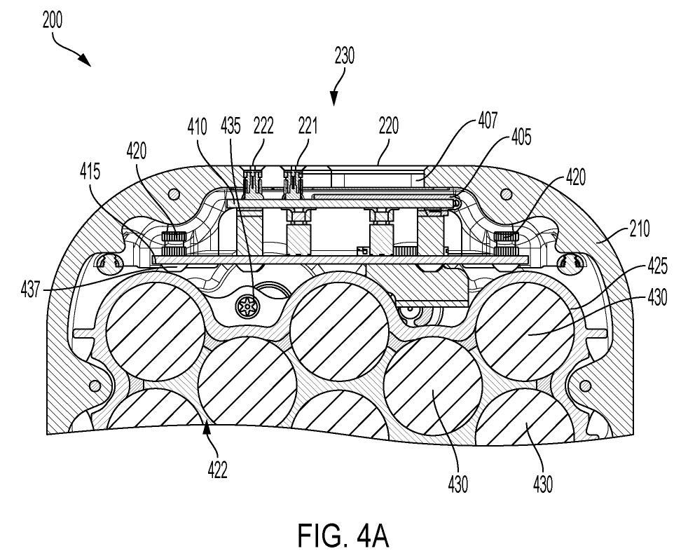

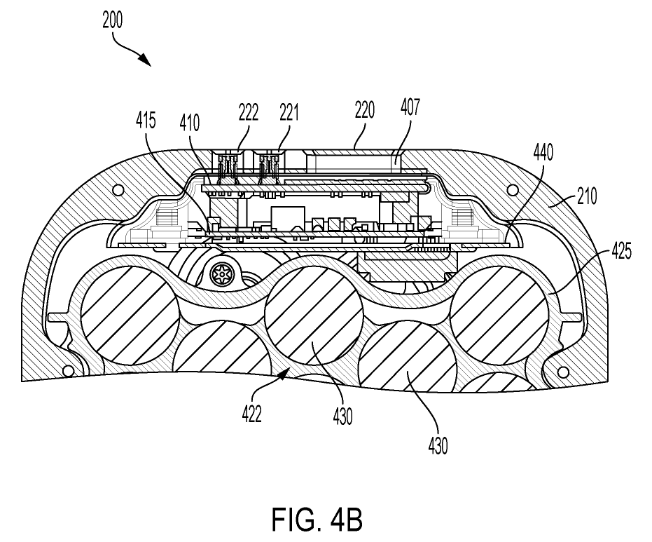

FIGS. 4A and 4B are perspective views of the assembly 200, in accordance with some aspects. The perspective view of the assembly 200, as shown in FIG. 4A, can refer to or include a bottom view of the assembly 200 where the bottom portion 215 has been removed from the assembly 200. Stated otherwise, the bottom portion 215 is removed such that a cavity, an internal portion, or an internal area of the housing 205 is visible. The assembly 200 can include at least one display device (shown as display device 405). The display device 405 can display, present, or otherwise provide the status 305. For example, the display device 405 can include an e-ink display to present the status 305.

The display device 405 can be disposed on or otherwise located on a printed circuit board (PCB). For example, and as shown in FIG. 4A, the display device 405 is disposed on a PCB 410. The PCB 410 can be included in an assembly or sub-assembly of the assembly 200. For example, the PCB 410 can be included in a display assembly of the assembly 200. The PCB 410 can house or otherwise include circuitry, hardware, or electronic components. For example, the PCB 410 can include a processor that is coupled with memory. As another example, the PCB 410 can include processing units that are coupled with one or more memory devices.

The display device 405 can refer to or include an always on display. For example, the display device 405 can continuously present the status 305 without a constant or semi-constant presence of voltage or a voltage level (e.g., no power or substantially no power). Stated otherwise, the display device 405 can maintain a presentation of the status 305 based solely on short-lived signals (e.g., a transient voltage level) such that the status 305 is still presented even after termination of the short-lived signals. The display device 405 can maintain presentation of the status 305 absent or without any subsequent receipt of a short-lived signal (e.g., a transient voltage level). The display device 405 can present or otherwise display the status 305 without an input or request to display the status 305. For example, the display device 405 can present the status 305 without a selection or interaction with a button or other input device of the assembly 200. As another example, the status 305 can be continuously present (e.g., always on) such that an operator of the assembly 200 can be presented with the status 305 upon viewing or otherwise looking at the aperture 220.

The display device 405 can be disposed proximate to a window or screen (of the assembly 200) such that the status 305 is visible or otherwise presented at an area that is external to the housing 205. For example, as shown in FIG. 4A, the display device 405 is disposed proximate to a window 407. The window 407 can be included in the housing 205 or a sub-housing of the housing 205.

The assembly 200 can include at least one PCB (shown as PCB 415). The PCB 415 can electrically couple the display device 405 or the PCB 410 with one or more portions, components, or elements of the assembly 200. The PCB 415 can include at least one plate through hole (PTH). For example, as shown in FIG. 4A, the PCB 415 includes a PTH 420 for which one or more fasteners 437 can couple the PCB 415 with the housing 205. The PCB 415 can include circuitry, hardware, or electrical components. For example, the PCB 415 can include a processor, that is coupled with memory, to determine, identify, or otherwise detect the status 305 (or changes to the status 305). As another example, the PCB 415 can include a processor, coupled with memory, to adjust the presentment of the status 305 by the display device 405. The PCB 410 and the PCB 415 (among other components) can refer to, include, or be included within a display assembly.

The assembly 200 can include at least one battery pack assembly (shown as battery pack assembly 422). The battery pack assembly 422 can refer to or include the battery pack 105. The battery pack assembly 422 can include at least one housing or sub-housing that is separate or discrete from the housing 205. For example, as shown in FIG. 4A, the battery pack assembly 422 includes a sub-housing 425. The sub-housing 425 can house, store, receive, or otherwise hold one or more battery cells (shown as battery cells 430). The sub-housing 425 can be removably coupled with the housing 205 via one or more fasteners 435. The battery pack assembly 422 can be stowed or otherwise disposed within the housing 205. For example, the battery pack assembly 422 can be positioned within a cavity or recess of the housing 205.

As shown in FIG. 4A, the PCB 410, the PCB 415, and the display device 405 (which can represent or be included within a display assembly) are disposed between an exterior surface (e.g., the front face 230) of the housing 205 and the battery pack assembly 422. Stated otherwise, the display assembly (of the assembly 200) is positioned within the housing 205 such that the front face 230 and the battery pack assembly 422 are located at respective sides or regions of the display assembly. The display device 405 can be interior to the exterior surface of the housing 205. For example, the display device 405 can be located within or otherwise disposed inside of the housing 205. As shown in FIG. 4A, the disposition, placement, or positioning of the display assembly (within the housing 205) can bring about or create an alignment between the display device 405 and the aperture 220. Stated otherwise, the display device 405 can be aligned with the aperture 220 as a result of the display assembly having been disposed or positioned between the front face 230 and the battery pack assembly 422.

The battery cells 430 can refer to or include at least one of rechargeable batteries, one or more energy storage devices, or other possible components that convert stored energy into electrical energy. The display device 405 can present, provide, or otherwise display a status (e.g., the status 305) of the battery cells 430. For example, the display device 405 can present an icon which illustrates the state of charge of the battery cells 430. As another example, the display device 405 can present a graphical element to indicate that the battery cells 430 are being charged.

Referring to FIG. 4B, among others, the assembly 200 includes a heat sink 440 that is disposed within the housing 205. The heat sink 440 can be coupled with or otherwise attached to the PCB 415. For example, the heat sink 440 can be coupled with the PCB 415 such that heat (produced by electronics of the PCB 415) is routed (via conduction) to the heat sink 440 for disbursement or dissipation. Stated otherwise, the heat sink 440 can dissipate heat that is produced by electrical components of the assembly 200. The heat sink 440 may or may not contact the housing 205. For example, there can be an air gap between the heat sink 440 and the housing 205. The assembly 200 can also include a biasing element such as a spring to impart a force on the heat sink 440 so that the heat sink 440 contacts the housing 205. A fastening element can also couple the heat sink 440 with the housing 205 to create contact between the heat sink 440 and the housing 205.

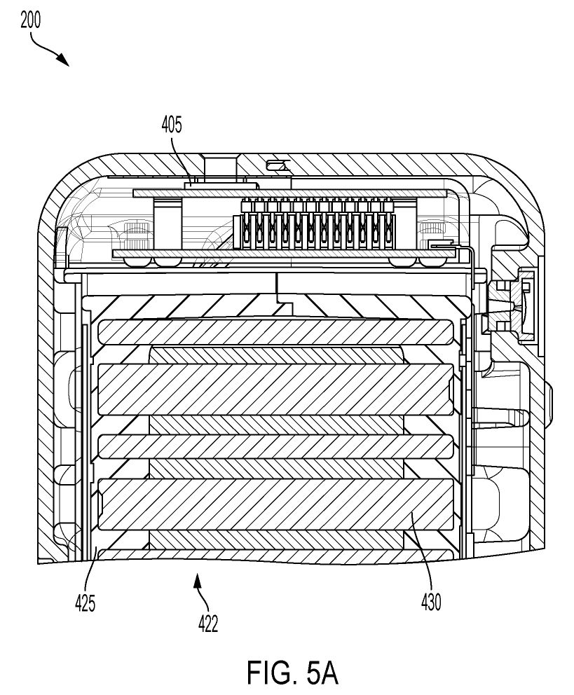

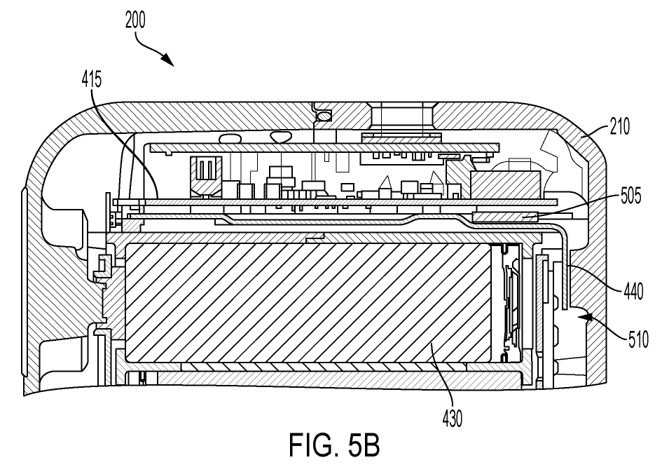

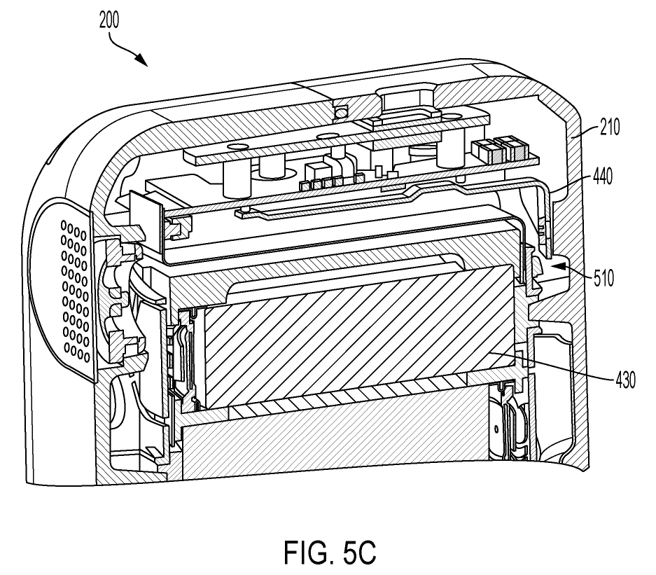

FIGS. 5A-5C are perspective example views of the assembly 200. The perspective view of the assembly 200, with reference to FIG. 5A, can refer to or include a cross-sectional view of the assembly 200. As shown in FIG. 5B, the heat sink 440 is coupled with the PCB 415 via a thermal element 505. The thermal element 505 can refer to or include thermal tape, thermal paste, or other possible elements to couple or otherwise attach the heat sink 440 with the PCB 415.

The heat sink 440 can route heat from the PCB 415 to at least one portion of or defined by the housing 205. This portion can be the same portion that receives heat from the battery cells 430. For example, as shown in FIGS. 5B and 5C, the heat sink 440 can route heat from the PCB 415 to an area or volume defined at least in part by the housing 205, such as at least one portion 510 of the assembly 200. The portion 510 can be internal or otherwise within the housing 205. The portion 510 can correspond to a region, an area, volume, or a segment defined at least in part by part of the housing 205. This portion 510 can include an air chamber or other volume for thermal coupling with both the PCB 415 and the battery cells 430 to cool or otherwise regulate the temperature of both the PCB 415 and the battery cells 430. The portion 510 can include active cooling elements (e.g., fans, fluid or liquid cooling) or passive elements such as fins to reduce or adjust a temperature of the PCB 415 or the battery cells 430.

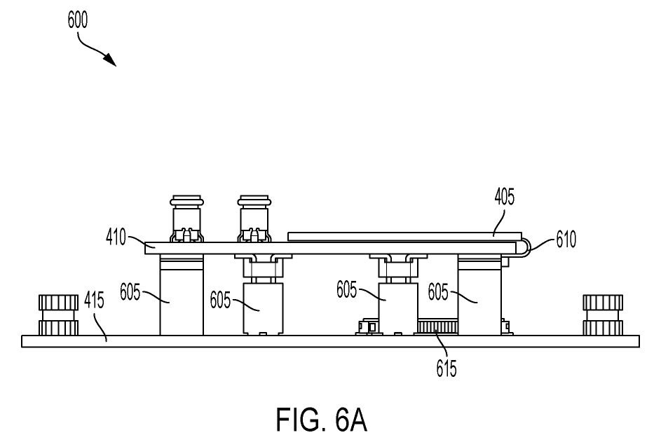

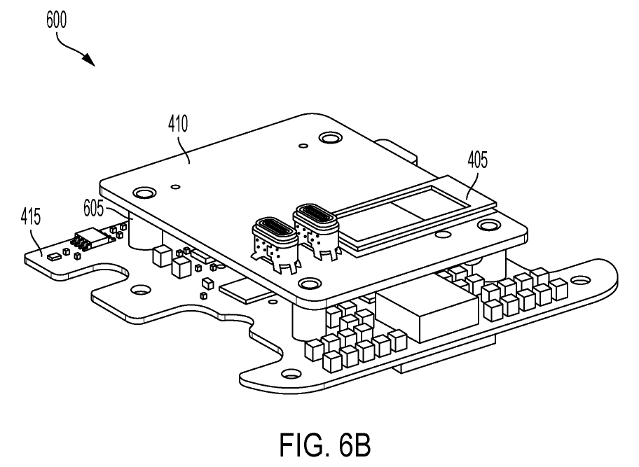

FIG. 6A and 6B depict a display assembly 600, in accordance with some aspects. The display assembly 600 can include at least one assembly, one or more devices, or one or more components described herein. For example, as shown in FIG. 6A, the display assembly 600 includes the display device 405. As another example, the display assembly 600 can include the PCB 410 and the PCB 415. As shown in FIGS. 6A and 6B, an overall dimension (e.g., a length and width) of the PCB 415 is larger than an overall dimension of the PCB 410. Stated otherwise, an overall size of the PCB 415 is larger than an overall size of the PCB 410.

With reference to FIG. 6A, the display device 405 is electrically coupled with the PCB 410 via a connector 610. The PCB 415 can support or otherwise hold the PCB 410 via one or more supports (shown as supports 605). As shown in FIGS. 6A and 6B, the display device 405 is disposed or otherwise positioned on the PCB 410, such that the placement of the display device 405 is proximate to a region of the PCB 410 that is supported by the supports 605. The PCB 415 can include one or more of computing devices, processing circuits, processors coupled with memory, microcontrollers, among other possible devices. For example, as shown in FIG. 6A, the PCB 415 includes at least one processor 615. The processor 615 can refer to or include one or more of a field programmable gate arrays (FPGA), an application specific integrated circuit (ASIC), a system-on-chip, or other types of circuitry.

The processor 615 can be communicably coupled with the battery cells 430 or a battery management system thereof via a controller area network (CAN) bus. The processor 615 can determine, identify, detect, or otherwise receive one or more statuses of the battery cells 430. For example, the processor 615 can determine the state of charge (e.g., a status) of the battery cells 430. As another example, the processor 615 can detect that the battery cells 430 are receiving electrical power or otherwise being charged (e.g., a status). The processor 615 can control the display assembly 600 or one or more components thereof such that the display device 405 presents the status 305. For example, the processor 615 can transmit one or more signals (such as a transient voltage level) to cause the display device 405 to present the status 305. As another example, the processor 615 can transmit signals to update the status 305.

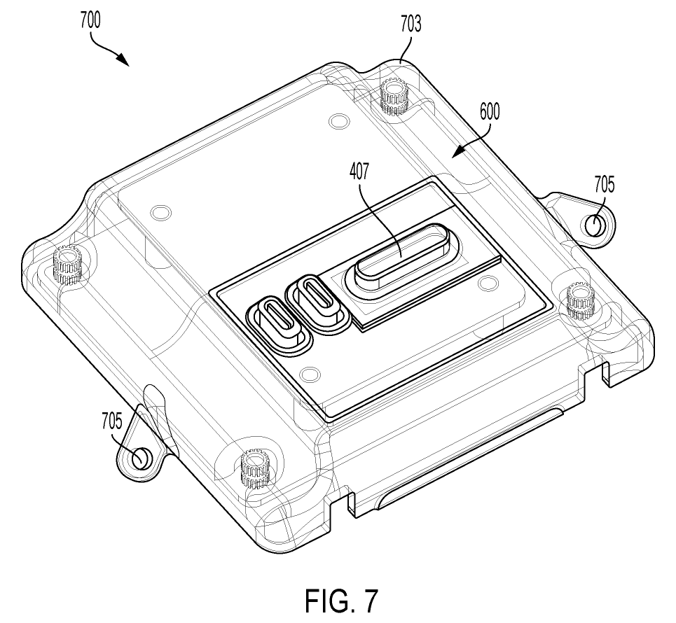

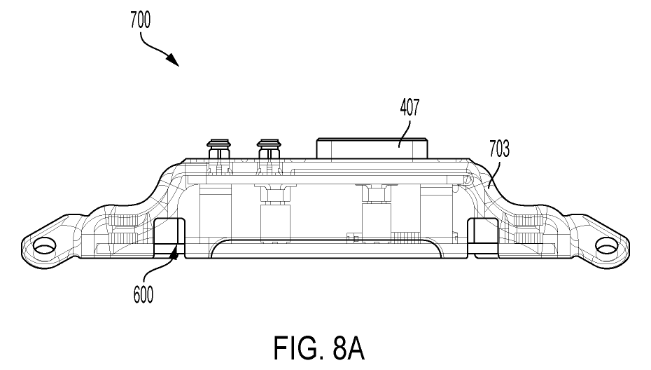

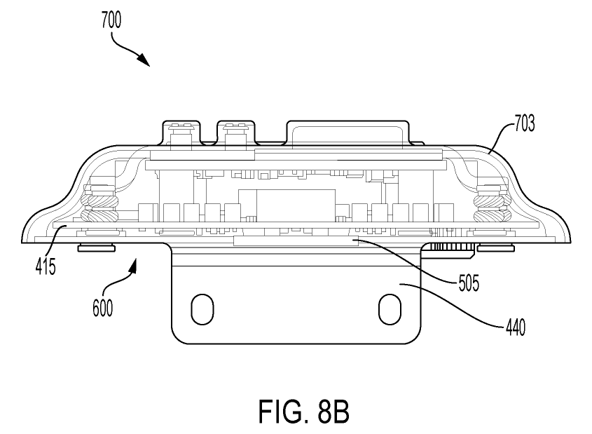

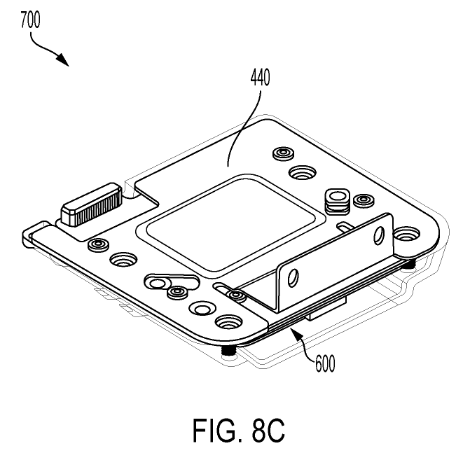

FIGS. 7, 8A, 8B, and 8C depict perspective views of a sub-assembly 700 of the assembly 200, according to some aspects. As shown in FIG. 7, the sub-assembly 700 includes the display assembly 600. The display assembly 600 can be at least partially disposed in or otherwise located in at least one housing or sub-housing that is separate to that of the housing 205. For example, and as shown in FIG. 7, the display assembly 600 is at least partially disposed within a sub-housing 703. The sub-housing 703 can receive or otherwise store the display assembly 600. The sub-housing 703 can receive, via one or more apertures 705, at least one fastener to couple the display assembly 600 with the housing 205. The sub-housing 703 can include or otherwise define the window 407.

As shown in at least FIGS. 7 and 8A, a dimension or size of the sub-housing 703 can correspond to a dimension of the display assembly 600. For example, the sub-housing 703 can be sized or dimensioned such that the display assembly 600 (while disposed in the sub-housing 703) is secured or otherwise situated to reduce or prevent movement of the display assembly 600 within the sub-housing 703. As another example, the sub-housing 703 can be dimensioned such that the display assembly 600 can be pressed into place within the sub-housing 703.

The heat sink 440 can include at least one segment or portion that spans a dimension of the display assembly 600 or one or more components thereof. For example, as shown in FIG. 8B, the heat sink 440 spans a dimension of the PCB 415. Stated otherwise, the heat sink 440 spans from a first side to a second side of the PCB 415. The heat sink 440 can include at least one segment or portion that spans a dimension of the sub-assembly 700. For example, as shown in FIG. 8C) the heat sink 440 spans a dimension (e.g., a first side to a second side) of the sub-housing 703.

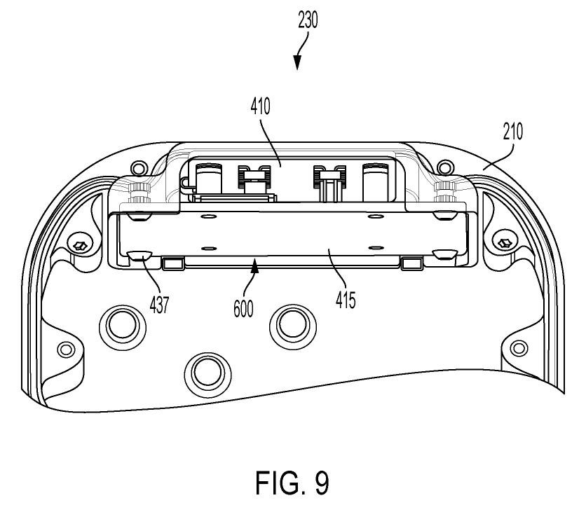

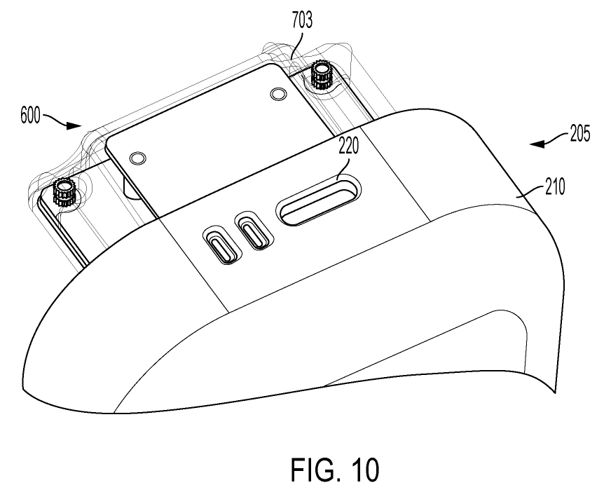

FIGS. 9-10 are perspective views of the display assembly 600, in accordance with some aspects. FIG. 9 depicts a perspective view of the display assembly 600 disposed within the housing 205 (and in particular the top portion 210). Moreover, FIG. 9 depicts an example of the battery pack assembly 422 having been removed or omitted from the assembly 200. Stated otherwise, the battery pack assembly 422 is not shown (in FIG. 9) to be disposed within the housing 205. FIG. 10 depicts a perspective view of the display assembly 600 at least partially disposed within the top portion 210. For example, the display device 405 can be disposed or otherwise positioned in the top portion 210. As described herein, the top portion 210 can be opposite to the bottom portion 215. As such the display assembly 600 (or other component, element, etc.) while disposed within the top portion 210 can be opposite to any component or element of the assembly 200 that is disposed within the bottom portion 215, such as the contacts 225.

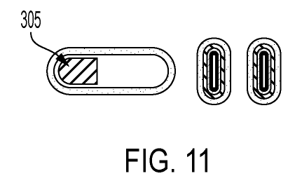

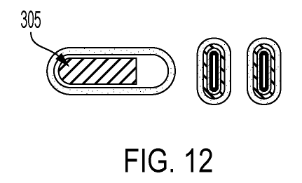

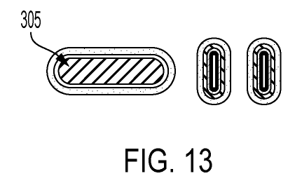

FIGS. 11-17 depict the status 305, in accordance with some aspects. As described herein, the display assembly 600 (or components, devices, or elements thereof) can display, present, provide, generate, or otherwise illustrate a status of one or more batteries. For example, the display device 405 can display the status 305 which represents a status of the battery cells 430. The status 305 can be visible, via the aperture 220, and through the window 407. FIGS. 11-13 depict example graphical or visual depictions of the status 305. For example, the status 305 is indicated by a dark portion (which represents the state of charge of the battery cells 430). The dark portion can represent a given percentage or energy amount for the battery cells 430. As shown in FIG. 13, the status 305 represents the battery cells 430 being at or near to 100% state of charge (e.g., full charge).

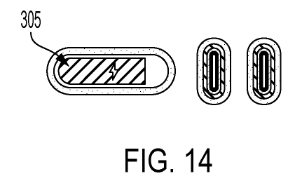

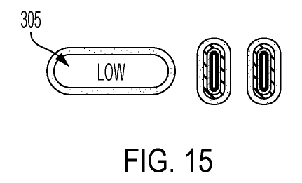

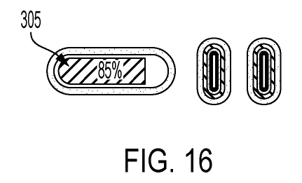

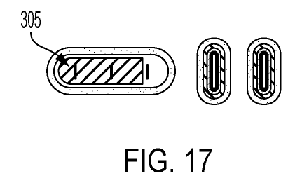

FIG. 14 depicts an example of the status 305 including an icon (shown as a lightning bolt) which represents or indicates that the battery cells 430 are being charged. FIG. 15 depicts an example of the status 305 indicating that the state of charge of the battery cells 430 is below a threshold (e.g., ultra-low voltage amount). FIG. 16 depicts an example of the status 305 including a numerical representation of the state of charge of the battery cells 430. FIG. 17 depicts an example of the status 305 including a hash style representation of the state of charge of the battery cells 430.

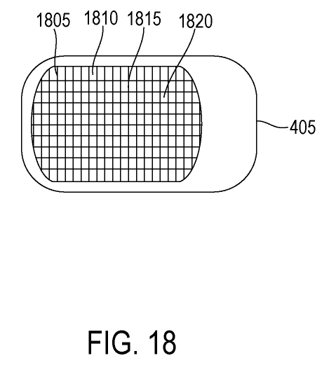

FIG. 18 depicts a perspective view of the display device 405, in accordance with some aspects. As shown in FIG. 18, the display device 405 includes a plurality of pixels (shown as pixel 1805, pixel 1810, pixel 1815, pixel 1820, among other pixels). The processor 615 can adjust or otherwise control the pixels (of the display device 405) to present or otherwise display the status 305. For example, the processor 615 can control one or more pixels (of the display device 405) to cause the pixels to be in a black state (e.g., a state of the pixels) to present information. As another example, the processor 615 can control one or more pixels to cause the pixels to be in a grey state (e.g., a state of the pixels) to present a grey space or a void within the display device 405. The processor 615 can control one or more subsets or segments of the pixels. For example, the processor 615 can change a state of a first subset of pixels (of the display device 405) while a second subset of pixels remains the same or unchanged. Stated otherwise, the processor 615 can update a status of a subset of pixels while statuses of other subsets of pixels are maintained or otherwise remain constant.

The processor 615 can change the status of pixels based on a change to the status of the battery cells. For example, the processor 615 can update or adjust a state for a subset of pixels to reflect a change to the state of charge for the battery cells. As another example, responsive to detection of a charging session (of the battery cells 430), the processor 615 can update the pixels to provide a visual indication that the battery cells 430 are being charged. The processor 615 can change the status of pixels by at least one of providing a current or applying a voltage to the pixels (or underlying microcells or microcapsules) such that the state of the pixels is changed. Stated otherwise, the system-on-chip can provide or apply a voltage to the pixels such that pixels switch between states or transition to a particular state.

As shown in FIG. 18, the pixels (of the display device 405) are arranged in a grid like pattern having one or more rows and one or more columns. The processor 615 can update one or more pixels that are within a particular row or a particular column. As another example, the processor 615 can update particular pixels based on stored entries which indicate a particular row and a particular column for each pixel of the display device 405. The stored entries can provide for granular or individual control of the pixels such that the processor 615 can adjust or update a state of single pixels (based on a status change) while states of other pixels can be maintained or otherwise remain unchanged.

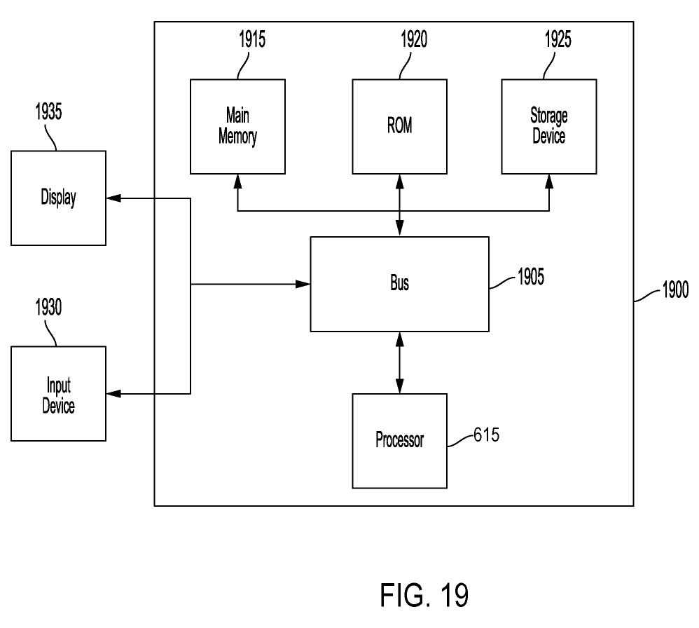

FIG. 19 is a block diagram illustrating an architecture for a computing system of a computer system (shown as computer system 1900) that can be employed to implement elements of the systems, methods, and assemblies described and illustrated herein. For example, the display assembly 600 can include the computer system 1900. The computer system 1900 can include at least one bus (shown as bus 1905) or other communication component for communicating information and at least one processor (shown as processor 615) or processing circuit coupled to the bus 1905 for processing information. The computer system 1900 can also include one or more processors or processing circuits coupled to the bus for processing information. The computer system 1900 also includes at least one main memory (shown as main memory 1915), such as a random access memory (RAM) or other dynamic storage device, coupled to the bus 1905 for storing information, and instructions to be executed by the processor 615. The main memory 1915 can be used for storing information during execution of instructions by the processor 615. The computer system 1900 may further include at least one read only memory (shown as ROM 1920) or other static storage device coupled to the bus 1905 for storing static information and instructions for the processor 615. A storage device 1925, such as a solid state device, magnetic disk or optical disk, can be coupled to the bus 1905 to persistently store information and instructions.

The computer system 1900 may be coupled via the bus 1905 to a display 1935, such as a liquid crystal display, or active matrix display, for displaying information to a user such as a rider of the bike 100 or other end user. An input device 1930, such as a keyboard or voice interface may be coupled to the bus 1905 for communicating information and commands to the processor 615. The input device 1930 can include a touch screen display, such as the display 1935. The input device 1930 can also include a cursor control, such as a mouse, a trackball, or cursor direction keys, for communicating direction information and command selections to the processor 615 and for controlling cursor movement on the display 1935.

The processes, systems and methods described herein can be implemented by the computer system 1900 in response to the processor 615 executing an arrangement of instructions contained in main memory 1915. Such instructions can be read into main memory 1915 from another computer-readable medium, such as the storage device 1925. Execution of the arrangement of instructions contained in main memory 1915 causes the computer system 1900 to perform the illustrative processes described herein. One or more processors in a multi-processing arrangement may also be employed to execute the instructions contained in main memory 1915. Hard-wired circuitry can be used in place of or in combination with software instructions together with the systems and methods described herein. Systems and methods described herein are not limited to any specific combination of hardware circuitry and software.

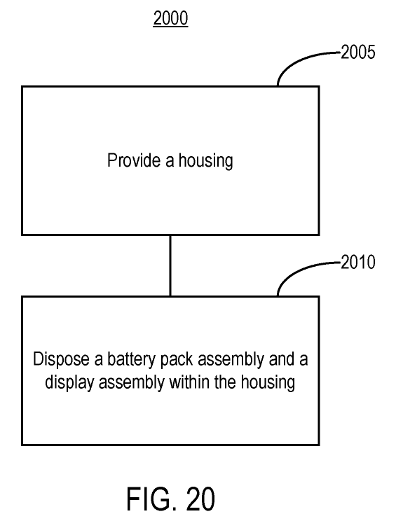

FIG. 20 depicts a flow diagram of a process 2000, in accordance with some aspects. The process 2000 can be implemented during assembly, manufacture, fabrication, or production of at least one component or element described herein. For example, the process 2000 can be implemented during fabrication of the assembly 200. As another example, the process 2000 can be implemented during assembly of the bike 100.

At act 2005, a housing can be provided. For example, the housing 205 can be provided. The housing 205 can be provided during the assembly or the manufacturing of the assembly 200. The housing 205 can be provided to establish or otherwise provide an area or a region (of the assembly 200) for which one or more components or elements of the assembly 200 can be stowed. The housing can be of an assembly. For example, the housing (provided in act 2005) can be for the assembly 200. The assembly 200 can be for the bike 100.

The housing 205 can receive or otherwise accept one or more components of the assembly 200. For example, the housing 205 can receive the battery pack assembly 422. As another example, the housing 205 can receive the display assembly 600. The housing 205 can receive one or more components by accepting or otherwise providing a region or an area for which the components can be positioned or otherwise disposed.

At act 2010, a battery pack assembly and a display assembly can be disposed within the housing. For example, the battery pack assembly 422 can be disposed within an internal portion of the housing 205. As another example, the battery pack assembly 422 can be positioned or otherwise placed within the housing 205. The display assembly 600 can be disposed within at least a portion of the housing 205. For example, the display assembly 600 can be disposed within the top portion 210. The display assembly 600 can be disposed within the housing 205 by at least one of placing, positioning, or locating the display assembly 600 within the housing 205.

The battery pack assembly 422 can include one or more battery cells. For example, the battery pack assembly can include the battery cells 430. The battery cells 430 can power at least one device. For example, the battery cells can provide power to a micromobility device, such as the bike 100. The battery cells 430 can provide power to one or more components of the bike 100. For example, the battery cells 430 can provide power to the drive mechanism 155. As another example, the battery cells 430 can provide power to the light 125.

The display assembly 600 can include at least one display device. For example, the display assembly 600 can include the display device 405. The display device 405 can present or otherwise depict a status of the battery cells 430. For example, the display device 405 can present the status 305. The display device 405 can continuously present the status of the battery cells 430. For example, the display device 405 can include an e-ink display that is always on or otherwise presents the status 305 without an input or receipt of a request to present the status 305. As another example, a receipt (by the display device 405) of a transient voltage level can alter a state (e.g., a state change) of one or more pixels of the display device 405 and the state can be maintained (e.g., continuously present) (i) even after the transient voltage level expires or terminates and (ii) until a subsequent transient voltage level is received.

The processor 615 can update or adjust states of pixels of an e-ink display (e.g., the display device 405) by selectively applying transient voltage levels to the e-ink display. The transient voltage levels can refer to or include at least one of temporary voltage levels, short-lived voltage levels, or otherwise non-permanent voltage levels. Stated otherwise, a transient voltage level is a voltage level that terminates or expires subsequent to a given time period having been reached. The processor 615 can apply a transient voltage level across one or more electrodes of the e-ink display device to trigger a change to the state of one or more pixels of the e-ink display. The processor 615 can apply the transient voltage level for a finite amount of time (e.g., a time period) or application interval. For example, the processor 615 can apply the transient voltage level for a time period that provides sufficient time for a complete transition of the pixels between states. The time period can include one or more amounts of time or time durations. For example, the time period can include at least 100 milliseconds, less than 500 milliseconds, more than 200 milliseconds, within a range of 50 milliseconds to 300 milliseconds, among other possible time periods.

The e-ink display can receive the transient voltage level at the electrodes. The receipt of the transient voltage level can establish an electric field within electrophoretic display material of one or more pixels. While the transient voltage level is present (e.g., prior to expiration of the time period) at the electrodes, the electric field can cause charged pigment particles within electrophoretic display material (of the pixels) to migrate. The migration of the electrophoretic display material can result in a transition of the one or more pixels from a first optical state to a second optical state. Upon expiration of the time period (e.g., the elapsed time is greater than the time period), the processor 615 can terminate the transient voltage level, and as such the transient voltage level is no longer present at the electrodes. As a result of the expiration of the time period, the electric field across the pixel electrodes collapses or otherwise dissipates.

Following the termination of the transient voltage level, the charged pigment particles (of the pixels) can remain in their respective positions within the electrophoretic display material due to bistable characteristics of the electrophoretic display material. Consequently, the e-ink display maintains (e.g., continuously presents) the second optical state of the one or more pixels in the absence of continued application of the transient voltage level. The maintained optical state can persist until the processor 615 (or other circuitry described herein) applies the transient voltage level once again or a different transient voltage level to the e-ink display. The reapplication of the transient voltage level or the application of the different transient voltage level can establish a subsequent electric field within the electrophoretic display material and thereby effect a further pixel state transition.

The micromobility device (referred to herein as bike 100) can be or include at least one drive unit (e.g., a propulsion system), at least one wheel, at least one battery pack, and a frame. The drive unit, the wheel, and the battery pack can be coupled with the frame. The drive unit can rotate the wheel to propel the micromobility device. The micromobility device can include the battery pack to power the drive unit and rotate the wheel with or without application of a mechanical force to a pedal assembly by the user. For example, the micromobility device can be propelled by a mechanical force provided by the user to the pedal assembly, by an electrical force provided by a battery pack to a motor, or some combination thereof. The micromobility device can include single rider bicycles, tandem bicycles, cargo bicycles, motor-assist bicycles, pedicabs, electric-assist bicycles, road bicycles, mountain bicycles, electric scooters, electric skateboards, standing devices, or unicycles, or devices with one, two, three, four or more than four wheels.

In various embodiments, a micromobility device (which may be or include the bike 100) can be designed to support a gross vehicle weight, defined as the combined mass of the device, rider, payload, and accessories, which corresponds to applicable regulatory or industry standards for micromobility devices. By way of example and without limitation, certain bicycle-based and electric bicycle standards, such as ISO 4210 and EN 15194, contemplate testing and design assumptions for a total mass on the order of approximately 120 kilograms, inclusive of rider and load, while other micromobility categories, including scooters, mopeds, and cargo-oriented devices, may be designed for higher gross vehicle weights, such as greater than 120 kilograms, greater than 150 kilograms, or greater than 200 kilograms, depending on jurisdiction, classification, and intended use. In some embodiments, the micromobility device may be configured to comply with regulations and testing protocols, such as those administered by the U.S. Consumer Product Safety Commission, which may specify structural strength, braking performance, and fatigue testing criteria corresponding to representative rider and payload masses. References to such weight values are intended to reflect regulatory examples rather than to impose fixed design limits on the disclosed embodiments.

The propulsion system may include an electric motor, a human-powered drivetrain, or a combination thereof, and may be configured in hub-based, mid-mounted, or remote arrangements using chain, belt, shaft, gear, friction, or direct-drive mechanisms to transmit torque to at least one ground-engaging element. An energy storage system may be provided to store electrical energy for powering the propulsion system and auxiliary components, and may include one or more batteries, capacitors, fuel cells, or other energy storage technologies that may be removable, fixed, swappable, or distributed across multiple locations on the device. The energy storage system may further include charging circuitry, battery management systems, thermal management components, and monitoring elements configured to meet or exceed applicable electrical standards for micromobility devices, including but not limited to UL 2849, UL 2272, IEC 62133, or equivalent regional or international standards.

The micromobility device may further include a control system comprising one or more processors, controllers, sensors, and communication interfaces configured to manage propulsion output, braking behavior, energy usage, and auxiliary functions. The control system may regulate motor output based on rider input, operating conditions, load, speed, inclination, or environmental sensing, and may support software-based features such as diagnostics, data logging, fleet management integration, geofencing, or over-the-air software updates. Braking systems may include mechanical, hydraulic, electromagnetic, regenerative, or combined braking mechanisms, and the device may further include stability or features such as traction control, anti-lock braking, suspension systems, steering dampening elements, lighting systems, and audible warning devices. In various embodiments, the micromobility device may be designed to comply with applicable operational and mechanical standards, including but not limited to ISO 4210, EN 15194, SAE J3194, applicable portions of 16 CFR Part 1512, and corresponding regional, national, or municipal micromobility regulations governing speed, power output, braking performance, lighting, and gross vehicle weight classifications.

The micromobility device may include a rider interface configured to receive user input through handlebars, grips, pedals, throttles, buttons, touch interfaces, or gesture-based controls, and may alternatively or additionally include a payload interface configured to support cargo, delivery containers, child seats, or autonomous payload modules. In some embodiments, the micromobility device may be configured as, or convertible between, multiple micromobility form factors, including electric bicycles, scooters, mopeds, seated or standing ride-on devices, or cargo and utility vehicles, wherein such configurations may share common components or differ only in selected structural, propulsion, control, or interface elements. Unless otherwise stated, the components and features described herein may be combined, omitted, rearranged, scaled, or substituted without departing from the scope of the disclosure, and references to regulatory standards or weight limits are intended to be exemplary and non-limiting.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C#, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device,” “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, and although many of the examples presented herein involve specific combinations of method acts or system elements, those acts and those elements may be combined in other ways to accomplish the same objectives. Acts, elements, and features discussed in connection with one implementation are not intended to be excluded from a similar role in other implementations or implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation,” or the like are not necessarily mutually exclusive and are intended to indicate that a particular feature, structure, or characteristic described in connection with the implementation may be included in at least one implementation or embodiment. Such terms, as used herein, are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A,’ only ‘B,’ as well as both ‘A’ and ‘B.’ Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

Further relative parallel, perpendicular, vertical, or other positioning or orientation descriptions include variations within +/-10% or +/-10 degrees of pure vertical, parallel or perpendicular positioning. References to “approximately,” “substantially,” or other terms of degree include variations of +/-10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. An assembly of a micromobility device, comprising:
a housing including an exterior surface defining at least one aperture;
one or more battery cells configured to power the micromobility device;
a display assembly; and
a battery pack assembly;
wherein:
the housing is configured to receive the battery pack assembly and the display assembly;
the display assembly is disposed interior to the exterior surface of the housing such that a display device aligns with the at least one aperture; and
the display device is configured to:
present a status of the one or more battery cells based on a power level of the one or more battery cells; and
maintain presentation of the status of the one or more battery cells while requiring substantially no power to maintain the presentation of the status.

2. The assembly of claim 1, comprising:
the display assembly including:
a processor;
a printed circuit board:
mechanically coupled with the display device; and
electrically coupling the display device with the processor; and
the processor configured to:
determine the status of the one or more battery cells; and
cause the presentation of the status of the one or more battery cells via the display device.

3. The assembly of claim 1, comprising:
the display assembly including a processor coupled with memory, the processor configured to control operation of the display device; and
a heat sink configured to:
route heat, produced by the processor, to a portion of the housing.

4. The assembly of claim 1, comprising:
the display device including a plurality of pixels having one or more states to present the status of the one or more battery cells; and
a processor, coupled with memory, configured to:
detect a change to the status of the one or more battery cells; and
transmit, to the display device, a transient voltage level to adjust the one or more states of a subset of the plurality of pixels to reflect the change to the status of the one or more battery cells.

5. The assembly of claim 4, wherein the one or more states of a second subset of the plurality of pixels are maintained as the one or more states of the subset of the plurality of pixels are adjusted.

6. The assembly of claim 1, comprising:
an electrical receptacle; and
the at least one aperture including:
a first aperture configured to align with the display device; and
a second aperture collocated with the first aperture, and the second aperture aligned with the electrical receptacle;
wherein the assembly is configured to provide bidirectional current flow via the electrical receptacle to charge the one or more battery cells and to power an external device.

7. The assembly of claim 1, wherein the display device includes an electronic ink display.

8. The assembly of claim 1, wherein the status of the one or more battery cells is presented without a request to present the status.

9. The assembly of claim 1, wherein the status of the one or more battery cells includes at least one of:
a state of charge of the one or more battery cells; or
an indication that energy is being provided to charge the one or more battery cells.

10. The assembly of claim 1, wherein the micromobility device is an electric bicycle.

11. An electric bicycle, comprising:
an assembly, comprising:
a housing including an exterior surface defining at least one aperture;
one or more battery cells to power the electric bicycle;
a display assembly; and
a battery pack assembly;
wherein:
the housing is configured to receive the battery pack assembly and the display assembly;
the display assembly is disposed interior to the exterior surface of the housing such that a display device aligns with the at least one aperture; and
the display device is configured to:
present a status of the one or more battery cells based on a power level of the one or more battery cells; and
maintain presentation of the status of the one or more battery cells while requiring substantially no power to maintain the presentation of the status.

12. The electric bicycle of claim 11, comprising:
the display assembly including:
a processor;
a printed circuit board:
mechanically coupled with the display device; and
electrically coupling the display device with the processor; and
the processor configured to:
determine the status of the one or more battery cells; and
cause the presentation of the status of the one or more battery cells via the display device.

13. The electric bicycle of claim 11, comprising:
the display assembly including a processor coupled with memory, the processor configured to control operation of the display device; and
a heat sink configured to:
route heat, produced by the processor, to a portion of the housing.

14. The electric bicycle of claim 11, comprising:
the display device including a plurality of pixels having one or more states to continuously present the status of the one or more battery cells; and
a processor, coupled with memory, configured to:
detect a change to the status of the one or more battery cells; and
transmit, to the display device, a transient voltage level to adjust the one or more states of a subset of the plurality of pixels to reflect the change to the status of the one or more battery cells.

15. The electric bicycle of claim 14, wherein the one or more states of a second subset of the plurality of pixels are maintained as the one or more states of the subset of the plurality of pixels are adjusted.

16. The electric bicycle of claim 11, comprising:
an electrical receptacle; and
the at least one aperture including:
a first aperture configured to align with the display device; and
a second aperture collocated with the first aperture, and the second aperture aligned with the electrical receptacle;
wherein the assembly is configured to provide bidirectional current flow via the electrical receptacle to charge the one or more battery cells and to power an external device.

17. The electric bicycle of claim 14, wherein the display device includes an electronic ink display.

18. The electric bicycle of claim 14, wherein the status of the one or more battery cells is continuously presented without a request to present the status.

19. A method, comprising:
providing a housing of an assembly of an electric bicycle, the housing including an exterior surface defining at least one aperture, the housing configured to receive a battery pack assembly and a display assembly; and
disposing the battery pack assembly and the display assembly within the housing, the battery pack assembly including one or more battery cells, and the one or more battery cells to power the electric bicycle;
wherein the display assembly is disposed interior to the exterior surface of the housing such that a display device aligns with the at least one aperture of the exterior surface, wherein the display device is configured to present a status of the one or more battery cells while requiring substantially no power to maintain presentation of the status.

20. The method of claim 19, wherein the display device includes a plurality of pixels having one or more states to present the status of the one or more battery cells, and further comprising:
detecting, by a processor coupled with memory, a change to the status of the one or more battery cells; and
adjusting, by the processor, the one or more states of a subset of the plurality of pixels to reflect the change to the status of the one or more battery cells.
